(19) United States
(12) Patent Application Publication
(10) Pub. No.: US 2021/0358883 A1
(43) Pub. Date: Nov. 18, 2021

(54) FAN-OUT PACKAGING METHOD EMPLOYING COMBINED PROCESS

(71) Applicant: SHENZHEN XIUYI INVESTMENT DEVELOPMENT PARTNERSHIP (LIMITED PARTNERSHIP), Shenzhen, Guangdong (CN)

(72) Inventors: Chuan HU, Shenzhen, Guangdong (CN); Yingqiang YAN, Shenzhen, Guangdong (CN); Yuejin GUO, Shenzhen, Guangdong (CN); Yingjun PI, Shenzhen, Guangdong (CN); Junjun LIU, Shenzhen, Guangdong (CN)

(21) Appl. No.: 17/284,571

(22) PCT Filed: Oct. 11, 2018
(86) PCT No.: PCT/CN2018/109772

§ 371 Date: Apr. 12, 2021

(51) Int. Cl. H01L 23/00

(52) U.S. Cl. CPC H01L 24/83; H01L 24/92; H01L 24/24; H01L 24/32; H01L 2224/24227; H01L 2224/83191; H01L 2224/8393; H01L 2224/32057; H01L 2224/32225; H01L 2224/92144

(57) ABSTRACT

A fan-out packaging method employing a combined process includes: manufacturing at least two layers of basic circuit patterns on a substrate; manufacturing a galvanic isolation layer on one of the two layers of basic circuit patterns; manufacturing a fine circuit pattern on the galvanic isolation layer; using a bonding layer to bond an electronic component to the galvanic isolation layer, and using a patch material to establish an electrical connection between the electronic component and the fine circuit pattern; and using a packaging layer to package the electronic component, wherein the fine circuit pattern has a width less than widths of the basic circuit patterns. In the present disclosure, multiple layers of circuits are manufactured before installation and packaging of electronic components, thereby reducing the number of times an insulation material is to be heated, and broadening the range of available types of insulation materials.

### TECHNICAL FIELD

The present disclosure pertains to the field of electronics and specifically relates to a fan-out packaging method employing a composite process (a combined process).

### BACKGROUND ART

Currently, a layer-by-layer plating method is used as a wiring method in fan-out packaging. According to this method, each metal/insulation layer formed on a surface of a reconstituted die must undergo a thermal curing treatment. As a result, the insulating material closest to the die should be thermally cured many times. In this way, the earliest layer of the packaging insulating medium has to undergo excessive thermal treatment processes, which may cause damage to the insulating material and its interface under the action of thermal stress.

### SUMMARY

In view of the above, the present disclosure is intended to overcome the drawbacks of the prior art and provide a fan-out packaging method employing a composite process, in which multiple layers of circuits are fabricated before electronic components are mounted and finally packaged, thereby reducing the number of thermal treatments to which an insulating material is subjected, and broadening the range of available types of insulating materials.

The technical solutions are disclosed as follows.

A fan-out packaging method employing a composite process includes: fabricating at least two layers of basic circuit patterns on a substrate; fabricating an electrical isolation layer on one of the basic circuit patterns; fabricating a fine circuit pattern on the electrical isolation layer; binding an electronic component to the electrical isolation layer by means of a patch material (or a bonding layer), and electrically connecting the electronic component to the fine circuit (fine line) via the patch material; and wrapping and packaging the electronic component in a packaging layer, wherein the fine circuit pattern has a wiring width smaller than that of the basic circuit patterns.

In one of the embodiments, the patch material is an anisotropic conductive film, or an insulating material for electric/magnetic field coupling or thermal compression binding, or a solder, or a no-flow underfill.

In one of the embodiments, the fine circuit is formed by a method such as physical vapor deposition, or chemical plating, or electroplating.

In one of the embodiments, in the process of binding the electronic component to the fine circuit, the substrate is attracted by vacuum or mechanically supported or attracted electrostatically so that the substrate is kept flat.

In one of the embodiments, at least two electronic components are connected to the fine circuit.

In one of the embodiments, the fine circuit layer has a wiring width of 0.5 μm to 30 μm.

In one of the embodiments, the basic circuit patterns each have a wiring width of 10 μm to 1,000 μm, and the basic circuit patterns are made by means of electroplating or etching.

In one of the embodiments, an interconnection hole is made in the substrate, wherein the interconnection hole is butted to the electronic component, and the interconnection hole is butted to the basic circuit pattern(s) or the fine circuit pattern.

In one of the embodiments, an interconnection layer is fabricated in the interconnection hole, and the interconnection layer electrically connects the electronic component to the basic circuit pattern(s), or the interconnection layer electrically connects the electronic component to the fine circuit pattern.

In one of the embodiments, the electronic component is provided on a first side of the substrate, and the interconnection hole is provided with an opening on a second side of the substrate; or the electronic component is provided on the second side of the substrate, and the interconnection hole is provided with an opening on the first side of the substrate.

In one of the embodiments, the basic circuit patterns are provided on both sides of the substrate.

The present disclosure has the following advantageous effects.

1. The fan-out packaging method employing a composite process includes: fabricating at least two layers of basic circuit patterns on a substrate. Multiple layers of basic circuit patterns are stacked on one another on the substrate. Either side of the substrate may be provided with one or more layers of basic circuit patterns or not provided with basic circuit patterns. Alternatively, one or more layers of basic circuit pattern substrates may be provided in the substrate. In this case, the basic circuit pattern(s) is similar to an interlayer(s) in the substrate. An isolation layer is fabricated on one of the layers of basic circuit patterns. A fine circuit pattern is fabricated on the isolation layer. The isolation layer provides isolation between the basic circuit pattern and the fine circuit pattern. An electronic component is bound to the electrical isolation layer by means of a patch material, and the electronic component is electrically connected to the fine circuit via the patch material. The electronic component is electrically connected to the basic circuit pattern. The fine circuit is connected or not connected to the basic circuit (basic line). A packaging layer is wrapped outside the electronic component. The electronic component is packaged in the packaging layer, and the fine circuit pattern may also be packaged in the packaging layer.

In this way, basic circuit patterns on a substrate are fabricated before electronic components are mounted to the substrate and finally packaged. A packaging layer that is actually in contact with dies does not undergo the thermal treatment process required in the fabrication of the basic circuit patterns. The packaging layer is subjected to a reduced number of thermal treatments so as to avoid aging of the packaging layer. Materials that are not resistant to thermal treatments in the traditional process are also applicable to the packaging layer in the present disclosure, and a wider range of materials are available for the packaging layer.

Here, the fine circuit pattern has a wiring width smaller than wiring widths of the basic circuit patterns. A more compact and denser fine circuit pattern can be fabricated with a smaller wiring width. The fine circuit pattern is closer to electronic components, so that the electronic components can be fanned out by means of the fine circuit pattern. A dense fine circuit pattern can provide more connection joints for electronic components. Moreover, it is easier to fabricate a fine circuit pattern on a substrate than on a surface of a reconstituted die.

Here, the electronic components include light-emitting dies, LED dies, wafers, packaged dies, bare dies, and electronic parts and elements required in various circuits.

2. The patch material is an anisotropic conductive film (ACF), an insulating material for electric/magnetic field coupling (capacitance or inductance) or thermal compression binding, a solder, a no-flow underfill, or the like. The patch material enables the interconnection of a die to the fine circuit.

3. The fine circuit layer has a wiring width of 0.5 μm to 30 μm. The basic circuit patterns each have a wiring width of 10 μm to 1,000 μm. The fine circuit layer is closer to electronic components. The electronic components need more connection wires. As the fine circuit pattern has a wiring width smaller than the wiring widths of the basic circuit patterns, denser circuits can be obtained to facilitate the electrical connection of electronic components, for example, fan-out/escape of dies.

4. Interconnection holes are made in the substrate. Each interconnection hole is butted to an electronic component. When there is no interconnection hole, the electronic component is blocked by the substrate and the packaging layer. After the interconnection hole is provided, the interconnection hole exposes the electronic component, and the electronic component can be electrically connected, via the interconnection hole, to the outside (for example, electrically connected to the basic circuit pattern or the fine circuit pattern, or connected to an external device such as a power supply). The interconnection hole is butted to the basic circuit pattern or the fine circuit pattern. When there is no interconnection hole, the basic circuit pattern or the fine circuit pattern is blocked by the substrate and the packaging layer. After the interconnection hole is provided, the interconnection hole exposes the basic circuit pattern or the fine circuit pattern, and the basic circuit pattern or the fine circuit pattern can be electrically connected, via the interconnection hole, to the outside (for example, electrically connected to an electronic component, or connected to an external device such as a power supply).

5. An interconnection layer is fabricated in each of the interconnection holes. The interconnection layer may be made of a conductive material or a semiconductor material. The interconnection layer electrically connects an electronic component to the basic circuit pattern, or the interconnection layer electrically connects an electronic component to the fine circuit pattern. The electronic component, the basic circuit layer, and the fine circuit layer can be electrically connected in an arbitrary way by means of providing an interconnection hole and an interconnection layer. The interconnection layer is provided in the interconnection hole without occupying additional space, whereby less space is required by the interconnection wires, so that the thickness of the packaged circuit board can be reduced, and a flexible circuit board can also be advantageously fabricated.

6. The electronic component is provided on a first side of the substrate, and the interconnection hole is provided with an opening on a second side of the substrate; or the electronic component is provided on the second side of the substrate, and the interconnection hole is provided with an opening on the first side of the substrate. When there is no interconnection hole, the electronic component is blocked by the substrate and the packaging layer. After the interconnection hole is provided, the interconnection hole exposes the electronic component, and an interconnection layer is fabricated in the interconnection hole through the opening of the interconnection hole. The interconnection hole may be made before the electronic component is mounted, or the interconnection hole may be made after the electronic component is mounted. When the electronic component is attached to the substrate using a patch material, the interconnection hole should extend through the patch material to expose the electronic component.

7. The basic circuit patterns are fabricated by using an etching method. The etching method has high mass production efficiency and requires low cost. The fine circuit pattern is fabricated by using a growth method. The growth method facilitates control of the width and precision of wiring in the fine circuit pattern and allows a denser fine circuit pattern to be obtained, but the growth method is performed with low efficiency at low speed.

The method of the present disclosure is compatible with an etching method and a growth method. Because the substrate has a relatively large size, circuit patterns with a large wiring width and low wiring density can be tolerated on the substrate. A basic circuit pattern is fabricated on the substrate with a low-cost and fast etching method. An isolation layer is fabricated on the basic circuit pattern, and a fine circuit pattern is fabricated on the isolation layer. The fine circuit pattern and the basic circuit pattern are isolated by the isolation layer without affecting each other. In the vicinity of electronic components, a fine circuit layer with a small wiring width and high wiring density should be fabricated on the isolation layer by using a high-cost and low-speed growth method. In this way, the cost can be reduced, and the overall production efficiency can be improved.

8. The basic circuit patterns are provided on both sides of the substrate. It is possible to fabricate an isolation layer and mount an electronic component on the basic circuit pattern on either side of the substrate.

9. The isolation layer is a dielectric layer. The electrical isolation layer may be placed on the surface of the substrate by a method, such as coating, spraying, mould pressing, chemical deposition, or physical deposition, and then cured. The curing process is usually performed by a thermal treatment.

10. The substrate is flexible; or a packaged circuit board that can be finally fabricated by the method of the present disclosure is a flexible printed circuit (FPC). A packaged circuit board is constituted by the substrate, the basic circuit patterns, the isolation layer, the fine circuit pattern, the electronic components, and the packaging layer as a whole. The packaged circuit board is flexible.

11. In the process of binding the electronic component to the fine circuit, the substrate is attracted by vacuum, or mechanically supported, or electrostatically attracted, so that the substrate is kept flat to ensure an alignment of the electronic component with the fine circuit. Thus, thinner fine connection wires can be fabricated.

### BRIEF DESCRIPTION OF THE DRAWINGS

FIG. 1 is a first step diagram of a fan-out packaging method employing a composite process according to an embodiment of the present disclosure;

FIG. 2 is a second step diagram of a fan-out packaging method employing a composite process according to an embodiment of the present disclosure;

FIG. 3 is a third step diagram of a fan-out packaging method employing a composite process according to an embodiment of the present disclosure;

FIG. 4 is a fourth step diagram of a fan-out packaging method employing a composite process according to an embodiment of the present disclosure;

FIG. 5 is a fifth step diagram of a fan-out packaging method employing a composite process according to an embodiment of the present disclosure;

FIG. 6 is a sixth step diagram of a fan-out packaging method employing a composite process according to an embodiment of the present disclosure;

FIG. 7 is a seventh step diagram of a fan-out packaging method employing a composite process according to an embodiment of the present disclosure; and

FIG. 8 is an eighth step diagram of a fan-out packaging method employing a composite process according to an embodiment of the present disclosure.

### DESCRIPTION OF REFERENCE SIGNS

100, substrate; 101, interconnection hole; 102, interconnection layer; 200A, 200B, basic circuit pattern; 210, connection layer; 300, isolation layer; 400, fine circuit pattern; 500, electronic component; 510, patch material; 600, packaging layer.

### DETAILED DESCRIPTION OF THE EMBODIMENTS

The present disclosure will be described in further detail below, but the embodiments of the present disclosure are not limited thereto.

First, circuit patterns of a substrate 100 are fabricated. Then, an electronic component 500 is mounted and finally packaged.

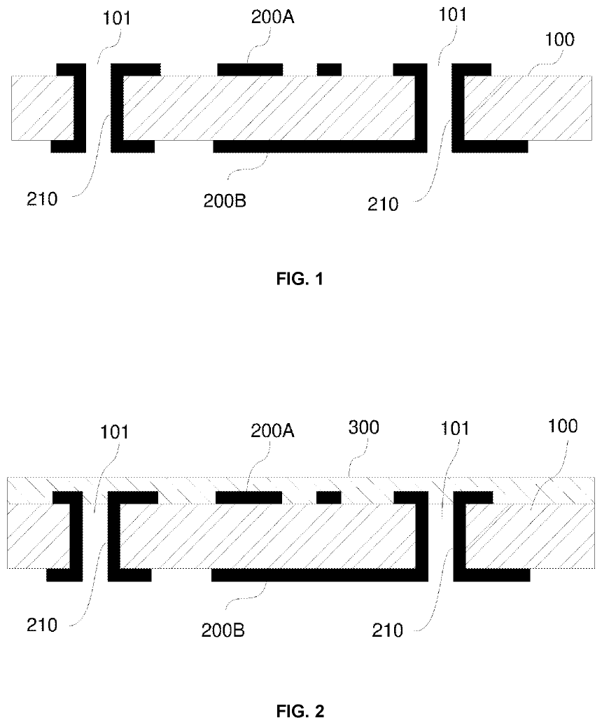

As shown in FIGS. 1 to 8, the fan-out packaging method employing a composite process includes the following steps.

As shown in FIG. 1, basic circuit patterns 200A and 200B are fabricated on the two sides of the substrate 100, respectively. In this embodiment, the substrate 100 is provided with two layers of basic circuit patterns 200A and 200B, but it is not limited thereto. Three or more layers of basic circuit patterns 200A and 200B may be provided on the substrate 100. The substrate 100 is provided with an interconnection hole 101. The interconnection hole 101 communicates the two sides of the substrate 100 with each other. A connection layer 210 is provided in the interconnection hole 101. The connection layer 210 electrically connects the basic circuit pattern 200A and the basic circuit pattern 200B on the two sides of the substrate 100. The connection layer 210 may be made by electroplating or other processes.

Here, the basic circuit patterns 200A, 200B are made by an etching method, including, but not limited to, processes such as photolithography, wet etching, and dry etching.

As shown in FIG. 2, an isolation layer 300 is fabricated on the basic circuit pattern 200A. The isolation layer 300 is used for isolating the basic circuit patterns 200 from a fine circuit pattern 400 in the subsequent process, to avoid mutual interference therebetween. In this embodiment, a dielectric layer is used as the isolation layer 300, and the dielectric layer is laminated on the substrate 100 so that the dielectric layer covers the surface of the basic circuit pattern 200A. However, it is not limited to this embodiment. The isolation layer 300 may be made of any other material capable of isolating the fine circuit pattern 400 from the basic circuit patterns 200.

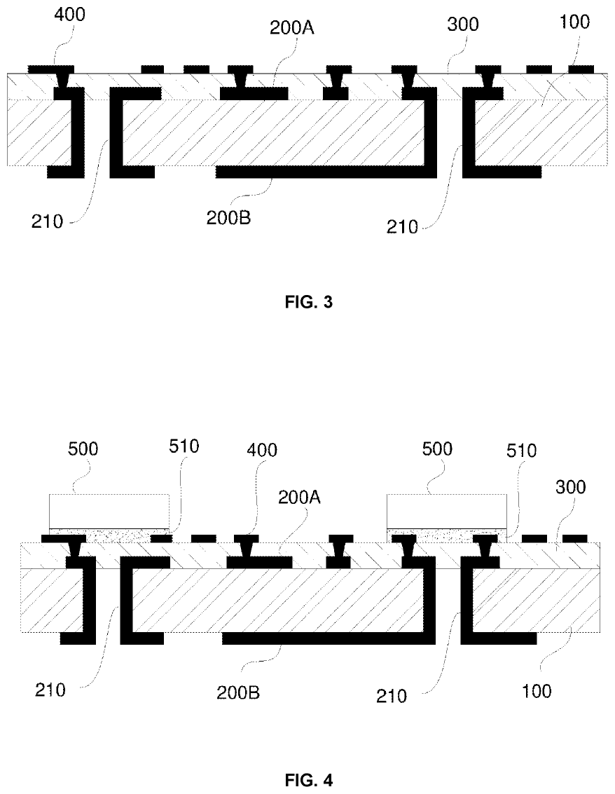

As shown in FIG. 3, a fine circuit pattern 400 is fabricated on the isolation layer 300. The isolation layer 300 provides isolation between the basic circuit patterns 200 and the fine circuit pattern 400.

Here, the fine circuit pattern 400 is fabricated by a growth method, including, but not limited to, processes such as electroplating and sputtering.

As shown in FIG. 4, an electronic component 500 is bonded to the fine circuit pattern 400 by using a patch material 510. The patch material 510 is pre-deposited on Si wafers and/or other electronic components before singulation, and it may be a direct current conductive material or an electromagnetic alternating current conductive material, for creating an electrical connection between the electronic component 500 and the fine circuit pattern 400. The electronic component 500 is electrically connected or not connected to the basic circuit patterns 200. In this case, the electronic component 500 is electrically connected or not connected to the fine circuit pattern 400. The patch material is an anisotropic conductive film (ACF), or an insulating material for electrical/magnetic field coupling (capacitance or inductance) or thermal compression binding, or a solder, or a no-flow underfill, or the like. The patch material enables the interconnection of a die to the fine circuit.

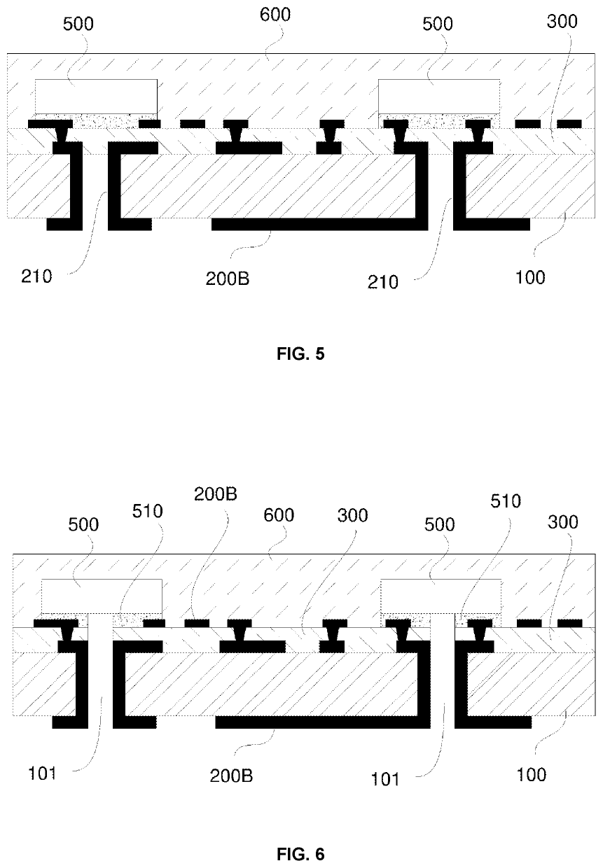

As shown in FIG. 5, a packaging layer 600 is wrapped around the electronic component 500. The electronic component 500 and the fine circuit pattern 400 are packaged in the packaging layer 600. The packaging layer 600 may be made of a thermosetting material such as an epoxy resin, or a thermoplastic insulating material such as a liquid crystal polymer material.

After the above steps are performed, the interconnection hole 101 and the electronic component 500 are blocked from each other by the isolation layer 300 and by the patch material 510. Thus, as shown in FIG. 6, the channel between the interconnection hole 101 and the electronic component 500 is opened so that the interconnection hole 101 extends through the isolation layer 300 and the patch material 510 and is butted to the electronic component 500. In the direction as shown in FIG. 6, the electronic component 500 is on the upper side of the substrate 100, and the interconnection hole 101 is provided with an opening on the lower side of the substrate 100. The interconnection hole 101 exposes pins of the electronic component 500 (although the pins of the electronic component 500 are not shown in the figure, it can be considered that the pins of the electronic component 500 are located at a side of the bottom of the electronic component 500 adjacent to the substrate 100). The pins of the electronic component 500 are exposed from the interconnection hole 101 to facilitate the connection of the electronic component 500.

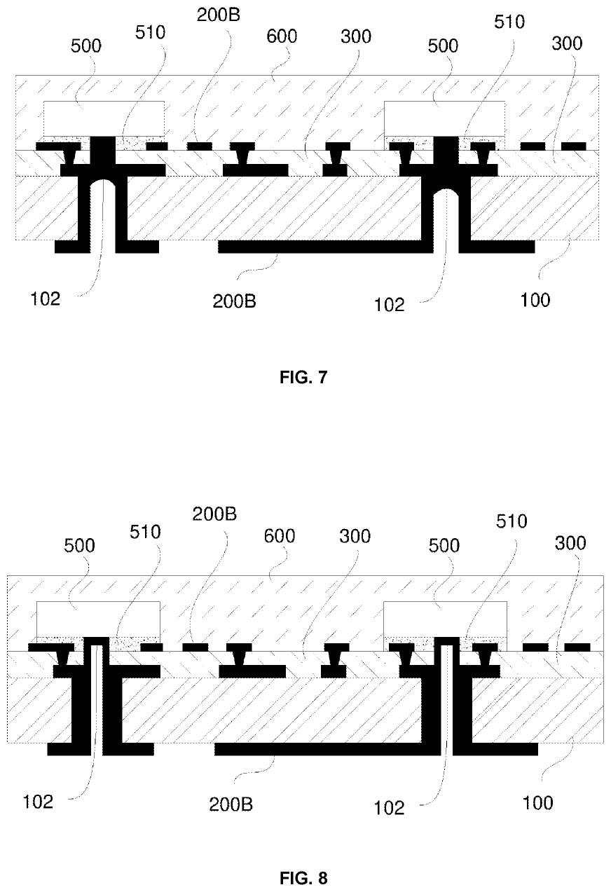

As shown in FIGS. 7 and 8, an interconnection layer 102 is fabricated in the interconnection hole 101 for electrically connecting the electronic component 500. The interconnection layer 102 may be made of a conductive material or a semiconductor material. The interconnection layer 102 electrically connects the electronic component 500 to the basic circuit patterns 200, or the interconnection layer 102 electrically connects the electronic component 500 to the fine circuit pattern 400.

In this way, basic circuit patterns 200 on the substrate 100 are first fabricated, and then an electronic component 500 is mounted to the substrate 100, and finally the electronic component 500 is packaged. The packaging layer 600 is not involved in the thermal treatment processes required in the fabrication of the basic circuit patterns 200. The packaging layer 600 is subjected to a reduced number of thermal treatments so as to avoid aging of the packaging layer 600. Materials that are not resistant to thermal treatments in the traditional process are also applicable to the packaging layer 600 in the present disclosure, and a wider range of materials are available for the packaging layer 600.

Here, the fine circuit pattern 400 has a wiring width smaller than the wiring widths of the basic circuit patterns 200. A more compact and denser fine circuit pattern 400 can be fabricated with a smaller wiring width. The fine circuit pattern 400 is closer to electronic components 500, so that the electronic components 500 can be fanned out by means of the fine circuit pattern 400. The dense fine circuit pattern 400 can provide more connection joints for the electronic components 500.

Here, the electronic components 500 include, but are not limited to, light-emitting dies, LED dies, wafers, packaged dies, bare dies, and electronic parts and elements required in various circuits.

The connection mode is not limited to those shown in FIGS. 7 and 8 and may be selected from any combinations of the following connection modes.

a. The interconnection layer 102 electrically connects the electronic component 500 to the fine circuit pattern 400. The fine circuit pattern 400 may have a smaller wiring width than those of the basic circuit patterns 200, and the fine circuit pattern 400 may be provided with denser connection wires for providing more connections for the electronic component 500. Preferably, the fine circuit layer has a wiring width of 0.5 μm to 30 μm. The basic circuit patterns 200 each have a wiring width of 10 μm to 1,000 μm. The fine circuit layer is closer to the electronic component 500. The electronic component 500 needs more connection wires. As the fine circuit pattern 400 has a wiring width smaller than those of the basic circuit patterns 200, denser circuits can be obtained to facilitate the electrical connection of electronic components 500, for example, fan-out/escape of electronic components 500. For example, a lot of connections are required for interconnection between two electronic components 500. Both of the electronic components 500 are electrically connected to the fine circuit pattern 400. The two electronic components 500 are connected to and communicated with each other by dense connection wires of the fine circuit pattern 400.

b. The interconnection layer 102 electrically connects the electronic component 500 to any layer of basic circuit pattern 200.

c. The interconnection layer 102 electrically connects the electronic component 500 to the connection layer 210, and then the electronic component 500 is electrically connected to the fine circuit pattern 400 or the basic circuit patterns 200 or other components by means of the connection layer 210.

In this embodiment, the interconnection layer 102 and the connection layer 210 are both provided in the interconnection hole 101, but they are not limited thereto. A separate through hole may be provided such that a connection layer 210 is fabricated therein. The basic circuit patterns 200A and 200B on the two sides of the substrate 100 are electrically connected to each other by means of the connection layer 210. An interconnection hole 101 is additionally provided. An interconnection layer 102 is fabricated in the interconnection hole 101. The electronic component 500 is electrically connected to the basic circuit patterns 200 or the fine circuit pattern 400 by means of the interconnection layer 102.

FIGS. 7 and 8 show two different structures of the interconnection layer 102, which are related to the fabrication processes. A process method, including but not limited to, filler welding or electroplating, may be used. The structure of the interconnection layer 102 is not restricted as long as an electrical connection can be achieved.

The electronic components 500, the basic circuit patterns 200A and 200B, and the fine circuit pattern 400 can be electrically connected in an arbitrary way by providing interconnection holes 101 and interconnection layers 102. The interconnection layers 102 are provided in the interconnection holes 101 without occupying additional space, whereby less space is required by the interconnection wires, so that the thickness of the packaged circuit board can be reduced, and a flexible circuit board can also be advantageously fabricated.

In this embodiment, the substrate 100 is flexible. A packaged circuit board is constituted by the substrate 100, the basic circuit patterns 200A and 200B, the isolation layer 300, the fine circuit pattern 400, the electronic components 500, and the packaging layer 600 as a whole. The finally fabricated packaged circuit board is a flexible printed circuit (FPC). However, it is not limited to this embodiment. The method of the present disclosure is also suitable for fabricating a rigid packaged circuit board.

In this embodiment, the basic circuit patterns 200A and 200B are fabricated by using an etching method. The etching method has high mass production efficiency and requires low cost. The fine circuit pattern 400 is fabricated by using a growth method. The growth method facilitates control of the width and precision of wiring in the fine circuit pattern and allows a denser fine circuit pattern 400 to be obtained, but the growth method is performed with low efficiency at low speed. The method of the present disclosure is compatible with an etching method and a growth method. Because the substrate 100 has a relatively large size, circuit patterns with a large wiring width and low wiring density can be tolerated on the substrate. The basic circuit patterns 200A and 200B are fabricated on the substrate with a low-cost and fast etching method. An isolation layer 300 is fabricated on the basic circuit pattern 200, and a fine circuit pattern 400 is fabricated on the isolation layer 300. The fine circuit pattern 400 and the basic circuit patterns 200A, 200B are isolated by the isolation layer 300 without affecting each other. In the vicinity of electronic components 500, a fine circuit layer with a small wiring width and high wiring density should be fabricated on the isolation layer 300 by using a high-cost and low-speed growth method. In this way, the cost can be reduced, and the overall production efficiency can be improved.

The technical features of the above embodiments can be combined in an arbitrary way. For brevity of description, not all possible combinations of the technical features in the above embodiments are described herein. However, any non-contradictory combinations of these technical features should be deemed to fall within the scope of this specification.

The above embodiments only express several implementations of the present disclosure and should not be construed as limiting the scope of the disclosure, although they are described specifically in detail. It should be noted that some modifications and improvements can be made by those of ordinary skill in the art without departing from the concept of the present disclosure and will fall within the scope of protection of the present disclosure. Therefore, the scope of protection of the present disclosure should be defined by the appended claims.

1. A fan-out packaging method employing a composite process, comprising:
fabricating at least two layers of basic circuit patterns on a substrate;
fabricating an electrical isolation layer on one of the at least two layers of basic circuit patterns;
fabricating a fine circuit pattern on the electrical isolation layer;
binding at least one electronic component to the electrical isolation layer through a bonding layer, and electrically connecting the at least one electronic component to a fine circuit via the patch material; and
wrapping and packaging the at least one electronic component, using a packaging layer,
wherein the fine circuit pattern has a wiring width smaller than wiring widths of the basic circuit patterns.

2. The fan-out packaging method employing a composite process according to claim 1, wherein the patch material is pre-deposited on the at least one electronic component and it is either an anisotropic conductive film, or an insulating material for electric/magnetic field coupling or thermal compression binding, or a solder, or a no-flow underfill.

3. The fan-out packaging method employing a composite process according to claim 1, wherein the fine circuit is formed by a method including physical vapor deposition, or chemical plating, or electroplating.

4. The fan-out packaging method employing a composite process according to claim 1, wherein in a process of binding the at least one electronic component to the fine circuit, the substrate is attracted by vacuum, or mechanically supported, or attracted electrostatically, so that the substrate is kept flat.

5. The fan-out packaging method employing a composite process according to claim 1, wherein at least two electronic components are connected to the fine circuit.

6. The fan-out packaging method employing a composite process according to claim 1, wherein a fine circuit layer has a wiring width of 0.5 μm to 30 μm.

7. The fan-out packaging method employing a composite process according to claim 1, wherein the basic circuit patterns each have a wiring width of 10 μm to 1,000 μm, and the basic circuit patterns are made by means of electroplating or etching.

8. The fan-out packaging method employing a composite process according to claim 1, wherein at least one interconnection hole is made in the substrate, the at least one interconnection hole is butted to the at least one electronic component, and the at least one interconnection hole is butted to the basic circuit patterns or the fine circuit pattern.

9. The fan-out packaging method employing a composite process according to claim 8, wherein an interconnection layer is fabricated in the at least one interconnection hole, and the interconnection layer electrically connects the at least one electronic component to the basic circuit patterns, or the interconnection layer electrically connects the at least one electronic component to the fine circuit pattern.

10. The fan-out packaging method employing a composite process according to claim 8, wherein the at least one electronic component is provided on a first side of the substrate, and the at least one interconnection hole is provided with an opening on a second side of the substrate; or
the at least one electronic component is provided on the second side of the substrate, and the at least one interconnection hole is provided with an opening on the first side of the substrate.

11. The fan-out packaging method employing a composite process according to claim 1, wherein the basic circuit patterns are provided on both sides of the substrate.

12. The fan-out packaging method employing a composite process according to claim 2, wherein the basic circuit patterns are provided on both sides of the substrate.

13. The fan-out packaging method employing a composite process according to claim 3, wherein the basic circuit patterns are provided on both sides of the substrate.

14. The fan-out packaging method employing a composite process according to claim 4, wherein the basic circuit patterns are provided on both sides of the substrate.

15. The fan-out packaging method employing a composite process according to claim 5, wherein the basic circuit patterns are provided on both sides of the substrate.

16. The fan-out packaging method employing a composite process according to claim 6, wherein the basic circuit patterns are provided on both sides of the substrate.

17. The fan-out packaging method employing a composite process according to claim 7, wherein the basic circuit patterns are provided on both sides of the substrate.

18. The fan-out packaging method employing a composite process according to claim 8, wherein the basic circuit patterns are provided on both sides of the substrate.

19. The fan-out packaging method employing a composite process according to claim 9, wherein the basic circuit patterns are provided on both sides of the substrate.

20. The fan-out packaging method employing a composite process according to claim 10, wherein the basic circuit patterns are provided on both sides of the substrate.
